(19) United States
(12) Patent Application Publication
(10) Pub. No.: US 2019/0024237 A1
(43) Pub. Date: Jan. 24, 2019

(54) METHODS FOR METALIZING VIAS WITHIN A SUBSTRATE

(71) Applicant: Corning Incorporated, Corning, NY (US)

(72) Inventor: Shrisudersan Jayaraman, Horseheads, NY (US)

(21) Appl. No.: 16/015,563

(22) Filed: Jun. 22, 2018

Related U.S. Application Data
(60) Provisional application No. 62/534,881, filed on Jul. 20, 2017.

(51) Int. Cl. C23C 18/16; C03C 17/10; C23C 18/38; H01L 21/288; H01L 21/768

(52) U.S. Cl. CPC C23C 18/1603; C23C 18/1639; C03C 17/10; C23C 18/1687; C03C 2218/111; H01L 21/288; H01L 21/7688; C03C 2217/263; C23C 18/38

(57) ABSTRACT

Methods of metalizing vias are disclosed. A method of metalizing at least one via includes contacting a substrate with a sacrificial metal sheet. The substrate includes a first surface, a second surface, and the at least one via extending between the first surface and the second surface and the first surface or the second surface of the substrate contacts a surface of the sacrificial metal sheet. The method further includes applying a solution comprising metal ions to the substrate and the sacrificial metal sheet such that a Galvanic displacement reaction occurs between the sacrificial metal sheet and the metal ions in the solution until the metal ions form a metal coating on at least one surface of the at least one via.

This application claims the benefit of priority under 35 U.S.C. § 119 of U.S. Provisional Application Ser. No. 62/534,881 filed on Jul. 20, 2017 the content of which is relied upon and incorporated herein by reference in its entirety.

### BACKGROUND

### Field

The present specification generally relates to methods for metalizing vias within a substrate and, more specifically, to metalizing vias within a substrate using a Galvanic displacement process.

### Technical Background

Metallization is a process in semiconductor and microelectronics industries that allows through-substrate vias to act as electrical interconnects. Copper is one preferred metal due to its low electrical resistivity. Through hole connections have garnered interest in recent years as they enable thin silicon and glass via-based technologies that provide high packaging density, reduced signal path, wide signal bandwidth, lower packaging cost and extremely miniaturized systems. These three-dimensional technologies have a wide range of applications in consumer electronics, high performance processors, micro-electromechanical devices (MEMS), touch sensors, biomedical devices, high-capacity memories, automotive electronics and aerospace components.

Current processes available for filling vias with copper may include one or more of physical vapor deposition (PVD), chemical vapor deposition (CVD), paste-based processes, electroplating, deposition of barrier layer(s), deposition of seed layer(s), ion metal plasma (IMP) processes, and chemical mechanical planarization (CMP) processes. The CVD process is suited for small sized vias (3-5 μm diameter) with aspect ratios up to 20, but is not suitable for vias that are larger and deeper. The paste process consists of filling the vias with a paste containing copper and a suitable binder, followed by curing at about 600° C. in an inert atmosphere to prevent oxidation. The substrate (e.g., glass) is then subsequently polished or thinned to account for a 2-8 μm shrinkage of the copper fill during curing. High temperature curing poses the risk of breaking or bending of low-thickness glasses, in addition to the need to manage coefficient of thermal expansion (CTE) of the paste during curing which may lead to copper lifting from vias. Both the CVD process and the paste process are not manufacture-friendly due to their complexity and high cost.

Electroplating technology, which includes depositing barrier and seed layers onto the substrate and in the vias, followed by electrodeposition of a metal (e.g., copper) and thinning, may be better suited for high volume manufacturing due to its reduced complexity and cost, and is commonly used in the semiconductor industry. Some efforts at reducing the complexity of the electroplating process have not managed to eliminate the need for barrier or seed layers, which are typically deposited via a sputtering process, a PVD process, or a CVD process. Another issue with seeded electroplating is that obtaining a void-free fill may be challenging, as the deposition front is non-uniform along the depth of the via and renders itself to formation of voids. Complicated strategies, such as modification of solution chemistry (e.g., use of accelerators, inhibitors, brighteners, and/or the like), pulse reverse current profiles, and/or the like have been employed to prevent the formation of voids during electroplating. These modifications may increase the cost of the electroplating process. Other processes may require the use of an electric field and/or components that are conductive or resistant to an electrical current, which may add to the cost or may not be readily available.

Accordingly, a need exists for a process to metalize vias within a substrate that is simple, scalable, and low-cost.

### SUMMARY

In some embodiments, a method of metalizing at least one via includes contacting a substrate with a sacrificial metal sheet. The substrate includes a first surface, a second surface, and the at least one via extending between the first surface and the second surface and the first surface or the second surface of the substrate contacts a surface of the sacrificial metal sheet. The method further includes applying a solution comprising metal ions to the substrate and the sacrificial metal sheet such that a Galvanic displacement reaction occurs between the sacrificial metal sheet and the metal ions in the solution until the metal ions form a metal coating on at least a portion of one surface of the at least one via.

In some embodiments, a method of metalizing at least one via includes contacting a substrate with a sacrificial metal sheet. The substrate includes a first surface, a second surface, and the at least one via extending between the first surface and the second surface and the first surface or the second surface of the substrate contacts a surface of the sacrificial metal sheet. The method further includes placing the substrate and the sacrificial metal sheet in a solution bath including metal ions, removing the substrate and the sacrificial metal sheet from the solution bath after a Galvanic displacement reaction occurs between the sacrificial metal sheet and the metal ions in the solution, and separating the substrate from the sacrificial metal sheet. The Galvanic displacement causes the metal ions in the solution bath to form a metal coating on at least a portion of one surface of the at least one via.

In some embodiments, a method of metalizing at least one via includes contacting a substrate with an aluminum sheet. The substrate includes a first surface, a second surface, and the at least one via extending between the first surface and the second surface and the first surface or the second surface of the substrate contacts a surface of the aluminum sheet. The method further includes applying a solution containing copper ions, such as a copper sulfate solution, to the substrate and the aluminum sheet, resulting in a Galvanic displacement reaction between the aluminum sheet and copper ions in the solution containing copper ions until the copper ions form a copper coating on at least a portion of one surface of the at least one via.

Additional features and advantages of the embodiments described herein will be set forth in the detailed description which follows, and in part will be readily apparent to those skilled in the art from that description or recognized by practicing the embodiments described herein, including the detailed description which follows, the claims, as well as the appended drawings.

It is to be understood that both the foregoing general description and the following detailed description describe various embodiments and are intended to provide an overview or framework for understanding the nature and character of the claimed subject matter. The accompanying drawings are included to provide a further understanding of the various embodiments, and are incorporated into and constitute a part of this specification. The drawings illustrate the various embodiments described herein, and together with the description serve to explain the principles and operations of the claimed subject matter.

### BRIEF DESCRIPTION OF THE DRAWINGS

FIG. 1 schematically depicts an illustrative apparatus for coupling a substrate and a sacrificial metal sheet and applying a solution thereto according to one or more embodiments described and illustrated herein;

FIG. 2 depicts a flow diagram of an illustrative method of metalizing at least one via according to one or more embodiments described and illustrated herein;

FIG. 3 schematically depicts an illustrative substrate and an illustrative sacrificial metal sheet in an uncoupled relationship according to one or more embodiments described and illustrated herein;

FIG. 4 schematically depicts an illustrative substrate and an illustrative sacrificial metal sheet in a coupled relationship according to one or more embodiments described and illustrated herein;

FIG. 5 schematically depicts an illustrative substrate and an illustrative sacrificial metal sheet with a solution applied thereto according to one or more embodiments described and illustrated herein;

FIG. 6 schematically depicts an illustrative substrate, an illustrative sacrificial metal sheet, and a solution with a metal deposition front at a first surface of the sacrificial metal sheet according to one or more embodiments described and illustrated herein;

FIG. 7 schematically depicts an illustrative substrate, an illustrative sacrificial metal sheet, and a solution with an advancing metal deposition front within vias of the substrate according to one or more embodiments described and illustrated herein;

FIG. 8 schematically depicts an illustrative substrate having fully metalized vias according to one or more embodiments described and illustrated herein;

FIG. 9 schematically depicts an illustrative substrate with fully metalized vias once it has been removed from an illustrative sacrificial metal sheet and a solution according to one or more embodiments described and illustrated herein; and

FIG. 10 is a photographic image of a glass substrate having copper filled vias by an exemplary metallization process described and illustrated herein.

### DETAILED DESCRIPTION

Reference will now be made in detail to embodiments of the present disclosure, examples of which are illustrated in the accompanying drawings. Whenever possible, the same reference numerals will be used throughout the drawings to refer to the same or like parts. Embodiments of the present disclosure are directed to metalizing vias of a substrate by a seedless electroplating process.

Embodiments described herein may bring a substrate (e.g., a glass substrate, glass-ceramic substrate, or a silicon substrate) with pre-patterned vias into contact with a sacrificial metal sheet. A solution containing metal ions (e.g., ions of the metal to be deposited in the vias) is introduced to the substrate and the sacrificial metal sheet. The metal of the sacrificial metal sheet has standard redox potential (E⁰) that is more negative (more reactive) than the E⁰ of metal of the metal ion in the solution. A Galvanic displacement reaction occurs between the sacrificial metal sheet and the metal ions in the solution, thereby causing the metal ions to be deposited from the solution onto the surface(s) of the vias. The embodiments described herein do not require a seed layer accompanied with complicated void-mitigating strategies to fill the vias with metal. In addition, the embodiments described herein do not require catalyzing components that further complicate the procedure or necessitate additional equipment. The embodiments of the present disclosure allow for a simpler and more inexpensive process than chemical vapor deposition (CVD) and paste-fill processes, and eliminate the need for curing. The processes described herein may be applied to any metal system that can be electrodeposited and to any through via technology, for example through silicon vias or through glass vias.

Various methods of metalizing vias within a substrate are described in detail below.

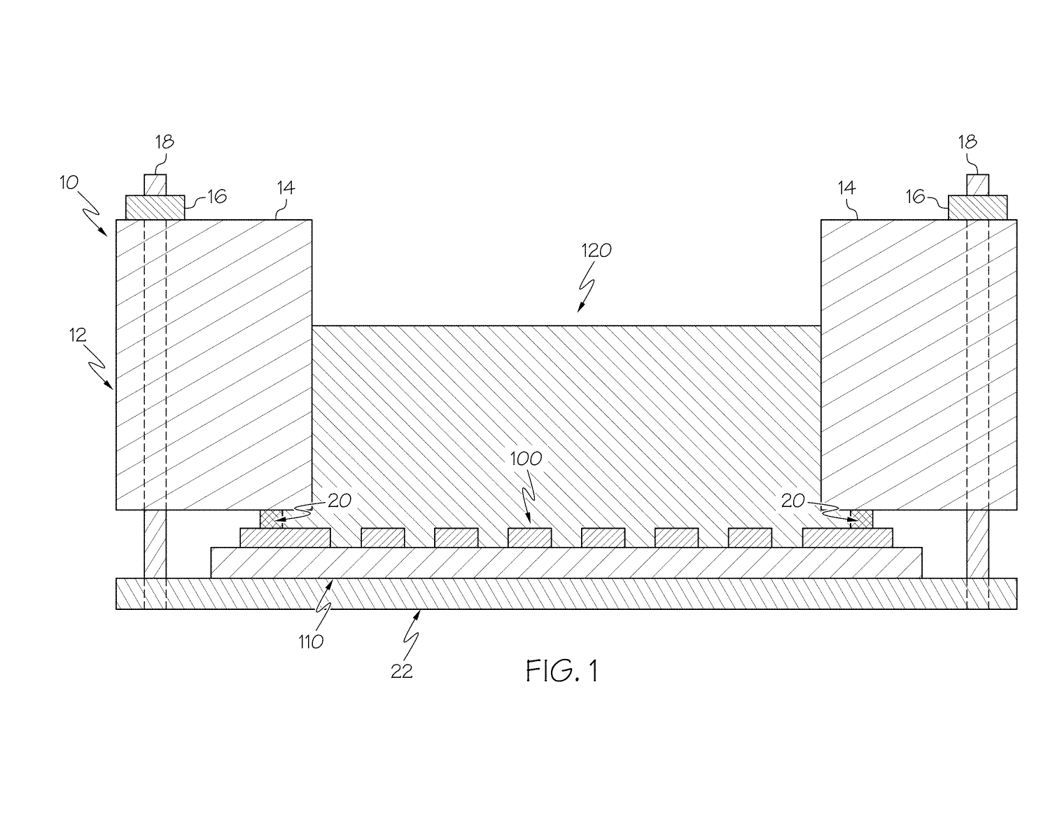

FIG. 1 depicts an illustrative apparatus, generally designated 10, that may be used for coupling a substrate 100 and a sacrificial metal sheet 110. The substrate 100 and the sacrificial metal sheet 110 may be placed in a solution 120, as will be described in greater detail herein.

In some embodiments, the apparatus 10 may include a first portion 12 (e.g., a top portion) and a second portion 22 (e.g., a bottom portion) that are mechanically coupled together via one or more components such as, for example, one or more nuts 16, one or more bolts 18, and/or the like. In some embodiments, the apparatus 10 may further include one or more protective devices 20, such as gaskets, seals, or the like (e.g., an o-ring) positioned between various components of the apparatus 10. For example, as shown in FIG. 1, the one or more gaskets 20 may be positioned between one or more sections 14 of the first portion 12 and one or more other components, such as, for example, the substrate 100.

The apparatus 10 may be arranged such that the first portion 12 and the second portion 22 provide a mechanical force on the substrate 100 and the sacrificial metal sheet 110 to cause a contact of the substrate 100 and the sacrificial metal sheet 110 and/or to maintain direct contact between the substrate 100 and the sacrificial metal sheet 110. For example, the one or more sections 14 of the first portion 12 may be arranged to contact the substrate 100 and the second portion 22 may be arranged to contact the sacrificial metal sheet. Each of the one or more sections 14 of the first portion 12 may be mechanically coupled to the second portion 22 by the one or more bolts 18 that extend between the one or more sections 14 of the first portion 12 and the second portion 22 and securely held by the one or more nuts 16 such that the substrate 100 and the sacrificial metal sheet 110 are sandwiched between the first portion 12 and the second portion 22.

In some embodiments, the one or more protective devices 20 may be placed between one or more components of the apparatus 10 and at least one of the substrate 100 and the sacrificial metal sheet 110 to absorb at least a portion of the compressive forces exerted by the apparatus on the substrate 100 and/or the sacrificial metal sheet 110, so as to avoid damage to the substrate 100 and/or the sacrificial metal sheet 110. For example, the one or more protective devices 20 may be arranged between the one or more sections 14 of the first portion 12 and the substrate 100 to absorb some of the pressure applied by the apparatus 10 such that the apparatus 10 does not cause the substrate 100 to break (e.g., shatter).

In some embodiments, the apparatus 10 may be further configured to be immersed in the solution 120, and/or coated with the solution 120 such that the solution also coats at least a portion of the substrate 100 and/or the sacrificial metal sheet 110, as described in greater detail herein. For example, the apparatus 10 (as well as the various components thereof) may be constructed of a material that does not corrode or otherwise break down after exposure to the solution 120. In some embodiments, the apparatus 10 may be configured to contain the solution 120 therein. That is, the apparatus 10 may function as a container having a cavity or the like, where the cavity receives and retains the solution 120, the substrate 100, the sacrificial metal sheet 110, and/or the various components described herein for applying a mechanical force to the substrate 100 and/or the sacrificial metal sheet 110.

It should be understood that the apparatus 10 is merely an illustrative example of an apparatus for maintaining contact between the substrate 100 and the sacrificial metal sheet 110. Other devices, such as clamps, weights, or the like, may also be used without departing from the scope of the present disclosure.

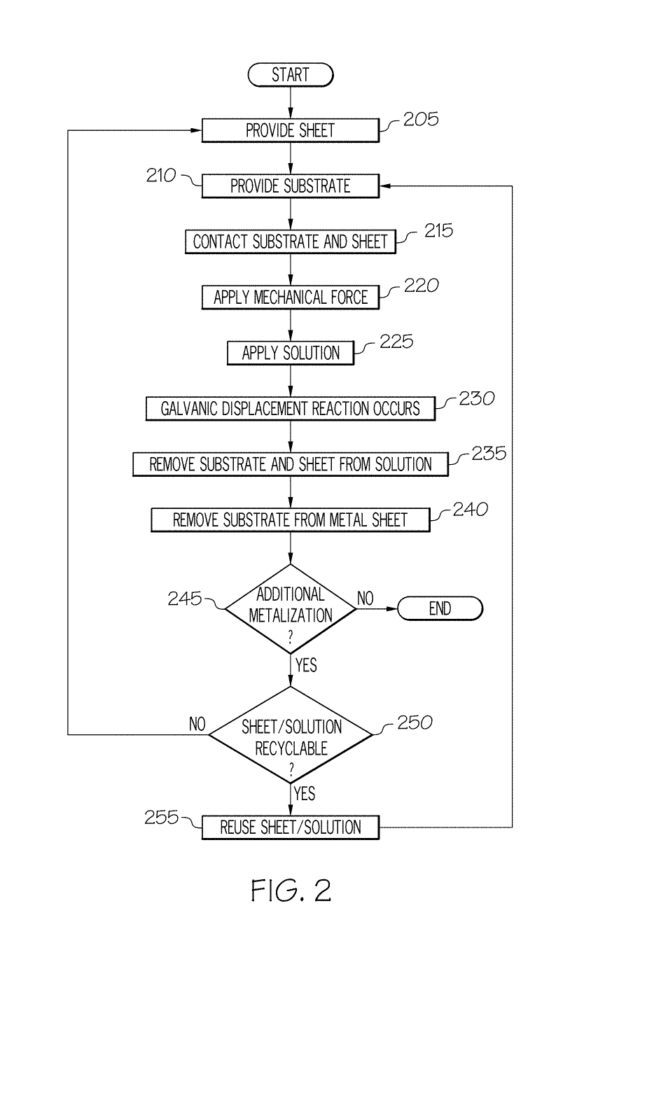

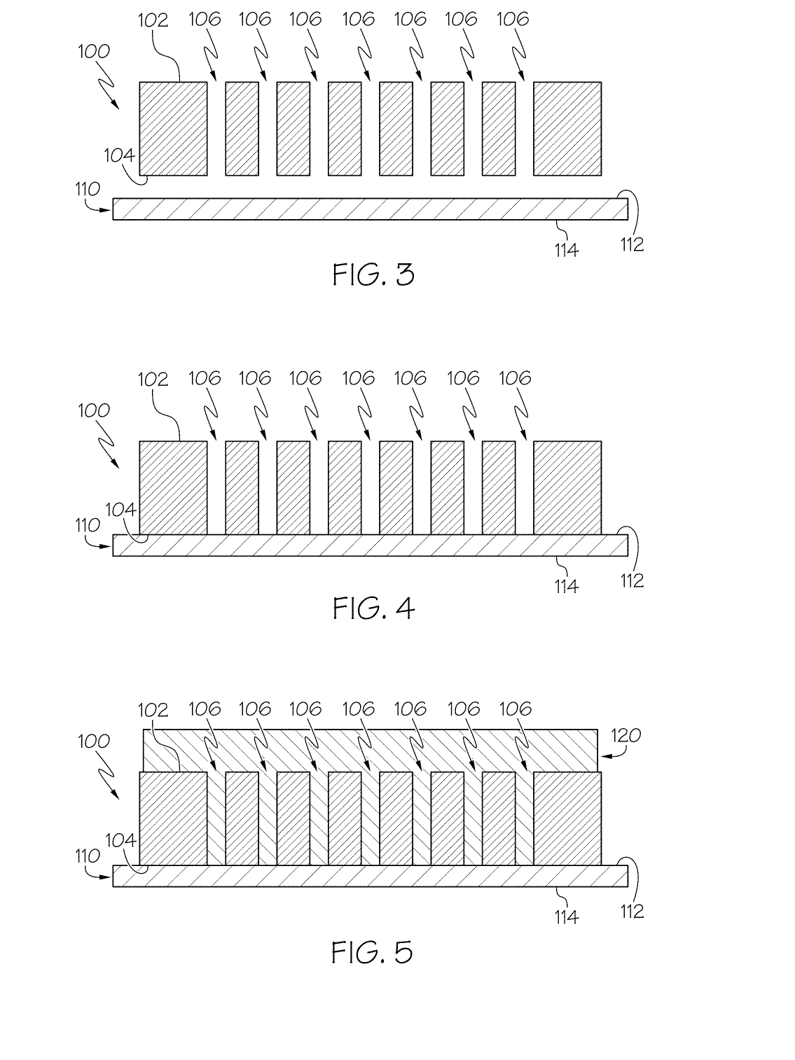

As described herein, the present disclosure relates to methods for metalizing vias by contacting the substrate 100 to the sacrificial metal sheet 110 and introducing the solution 120 to the substrate 100 and/or the sacrificial metal sheet 110 to allow a Galvanic displacement reaction to occur. FIG. 2 depicts a flow diagram of one such illustrative method. In some embodiments, one or more steps may be added and/or removed from the flow diagram of FIG. 2. At step 205, the sacrificial metal sheet may be provided, and at step 210, the substrate may be provided. Particular details with regards to providing the sacrificial metal sheet and the substrate will be described herein with respect to FIG. 3.

Still referring to FIG. 2, the substrate and the sacrificial metal sheet may be contacted at step 215. That is, the substrate may be brought into contact with the sacrificial metal sheet and/or a contact between the substrate and the sacrificial metal sheet may be maintained. As such, in some embodiments, a mechanical force may be applied to the substrate and/or the sacrificial metal sheet at step 220. For example, a compressive force may be applied to compress the substrate and the sacrificial metal sheet together. Contacting the substrate and sacrificial metal sheet and/or maintaining contact will be illustrated herein with respect to FIG. 4.

Still referring to FIG. 2, the solution may be applied to the substrate and/or the sacrificial metal sheet, which will be described in greater detail herein with respect to FIG. 5. At step 230, a Galvanic displacement reaction may occur. That is, the Galvanic displacement reaction may automatically occur upon contact of the solution with the substrate and/or the sacrificial metal sheet without the need for additional steps to cause the reaction to occur.

Galvanic displacement occurs when a metal that is more reactive (less noble) comes in contact with a solution containing ions of a less reactive (more noble) metal. For example, if the more reactive metal (N), such as the metal contained in the sacrificial metal sheet, comes in contact with a solution containing ions of a less reactive metal (M^{a+}), such as the metal contained within the solution described herein, the more reactive metal (N) will displace the less reactive metal (M^{a+}) in the solution and ionizes (N^{b+}), dissolving the solution. Consequently, the less reactive metal will be reduced to its metallic form (M), as represented by Equation (1) below:

bM^{a+}+aN→bM+aN^{b+} (1)

In one example, the sacrificial metal sheet may be an aluminum sheet and the solution may be a solution containing copper ions. That is, the solution may be a copper sulfate (CuSO₄) solution, a copper chloride (CuCl₂) solution, a copper nitrate (Cu(NO₃)₂) solution, and/or the like. As such, when the aluminum sheet is exposed to the solution containing the copper ions dissolved in the solution, the aluminum dissolves into ions (e.g., Al³⁺ ions) while the copper ions in the solution are reduced into copper metal, as represented by Equation (2) below:

3Cu²++2Al→3Cu+2Al³⁺ (2)

In another example, the sacrificial metal sheet may be an iron sheet and the solution may be a solution containing copper ions. That is, the solution may be a copper sulfate (CuSO₄) solution, a copper chloride (CuCl₂) solution, a copper nitrate (Cu(NO₃)₂) solution, and/or the like. As such, when the iron sheet is exposed to the solution containing the copper ions dissolved in the solution, the iron dissolves into ions (e.g., Fe²⁺ ions) while the copper ions in the solution are reduced into copper metal, as represented by Equation (3) below:

Cu²⁺+Fe→Cu+Fe²⁺ (3)

The relative reactivity of a particular metal/ion system may be determined from its standard redox potential, which is a thermodynamically determined quantity. It should be understood that there are standard tables available for a plurality of various metal/ion systems. A metal (e.g, M1) is considered to be more reactive relative to another metal (e.g., M2) if its standard redox potential (E^{0,1}) is more negative than that of the second metal (E^{0,2}). Illustrative examples of redox systems (in order of increasing reactivity) are depicted in Table 1 below. Accordingly, any combination of the metals listed below (or other metals) can be used as long as the metal of the sacrificial sheet has a more negative E° than the metal of the metal ion in the solution. For example the metal coating can be selected from the group consisting of copper, gold, silver, platinum, rhodium, lead, tin, nickel, cadmium, iron, chromium, and zinc when the sacrificial metal sheet is aluminum.

TABLE 1
Redox System Examples

| | |
|---|---|
| Au³⁺ + 3e⁻ [symbol] Au | E⁰ = +1.50 V |
| Pt²⁺ + 2e⁻ [symbol] Pt | E⁰ = +1.18 V |
| Ag⁺ + e⁻ [symbol] Ag | E⁰ = +0.80 V |
| Rh³⁺ + 3e⁻ [symbol] Rh | E⁰ = +0.76 V |
| Cu²⁺ + 2e⁻ [symbol] Cu | E⁰ = +0.34 V |
| Pb²⁺ + 2e⁻ [symbol] Pb | E⁰ = −0.13 V |
| Sn²⁺ + 2e⁻ [symbol] Sn | E⁰ = −0.14 V |
| Ni²⁺ + 2e⁻ [symbol] Ni | E⁰ = −0.26 V |
| Cd²⁺ + 2e⁻ [symbol] Cd | E⁰ = −0.40 V |
| Fe²⁺ + 2e⁻ [symbol] Fe | E⁰ = −0.45 V |
| Cr³⁺ + 3e⁻ [symbol] Cr | E⁰ = −0.74 V |
| Zn²⁺ + 2e⁻ [symbol] Zn | E⁰ = −0.76 V |
| Al³⁺ + 3e⁻ [symbol] Al | E⁰ = −1.66 V |

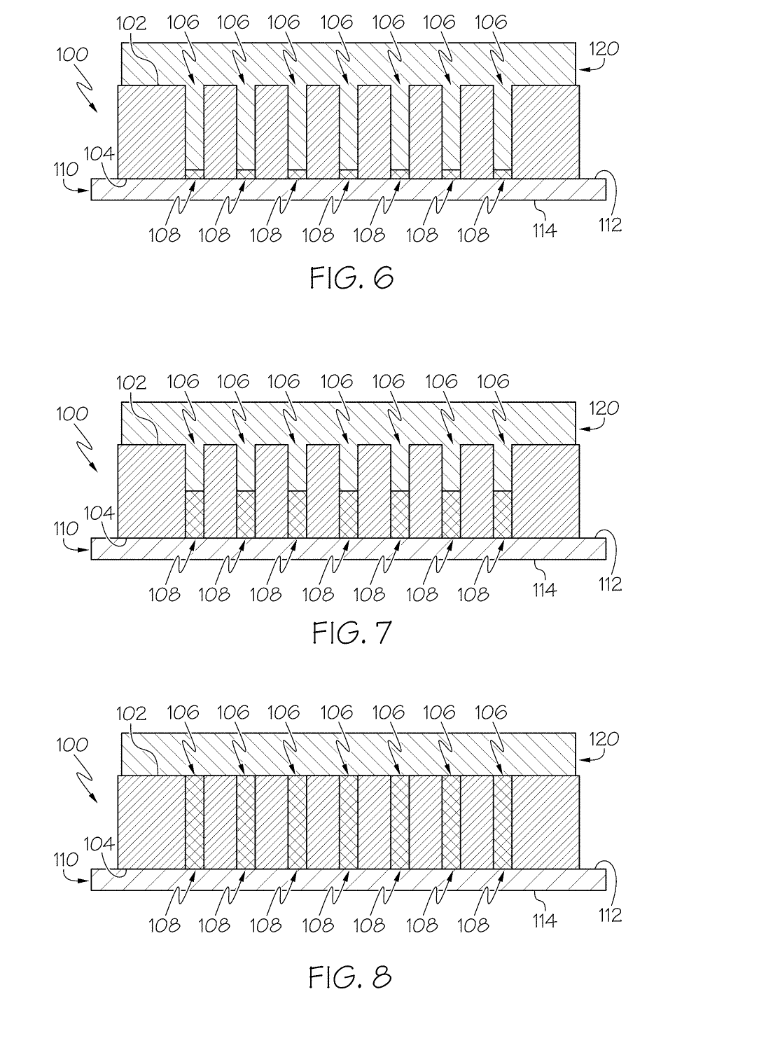

Accordingly, the metal in the sacrificial metal sheet reacts and dissolves as the metal ions in the solution (e.g., Aluminum metal dissolves as aluminum sulfate (Al₂SO₄)₃) into the solution) while the metal ions in the solution build up as a solid metal coating on the substrate. For example, when the sacrificial metal sheet is aluminum and the solution is copper sulfate, the aluminum metal dissolves as aluminum sulfate into the solution and the copper ions are reduced to copper metal and build up as a solid metal coating in the via(s) of the substrate. As this reaction continues, more and more of the metal from the sacrificial metal sheet dissolves into the solution, thus replacing the initial metal ions in the solution, which causes a build up of metal from the initial ions as solid metal in the via(s) the substrate. The continuous build-up is exploited to fill the through-substrate vias by forcing the growth direction through the vias, as depicted and described herein with respect to FIGS. 6-8. Filling the through-substrate vias may include partially filling one or more of the vias, fully filling one or more of the vias (e.g., such that an entire volume of a via is completely filled), or overfilling one or more of the vias (e.g., such that an excess amount of metal is deposited as overburden material on a top surface of the substrate). The principle of Galvanic displacement can be utilized to deposit any metal on the surfaces of the vias through an appropriate selection of the metal in the sacrificial metal sheet and the metal ions in the solution.

Still referring to FIG. 2, the substrate and/or the sacrificial metal sheet are removed from the solution at step 235. The substrate and/or the sacrificial metal sheet may be removed after a particular time has elapsed since the substrate and the sacrificial metal sheet were placed in the solution. For example, the particular amount of time may be a period of time that is sufficient for all of the vias in the substrate to be coated with the metal. In another example, the particular amount of time may be a predetermined amount of time, such as, but not limited to, 1 hour, 4 hours, 8 hours, 12 hours, 24 hours, 36 hours, 48 hours, 60 hours, 72 hours, 5 days, 10 days, or any value or range between any two of these values (including endpoints). In some embodiments, removal of the substrate and/or the sacrificial metal sheet from the solution may further include rinsing the substrate and/or the sacrificial metal sheet (e.g., rinsing with deionized water) to remove all of the solution therefrom. In some embodiments, the separation of the substrate and the sacrificial metal can be achieved by simply immersing the substrate-metal assembly in a water bath. This will dislodge the substrate from the sheet with the copper in the vias staying intact.

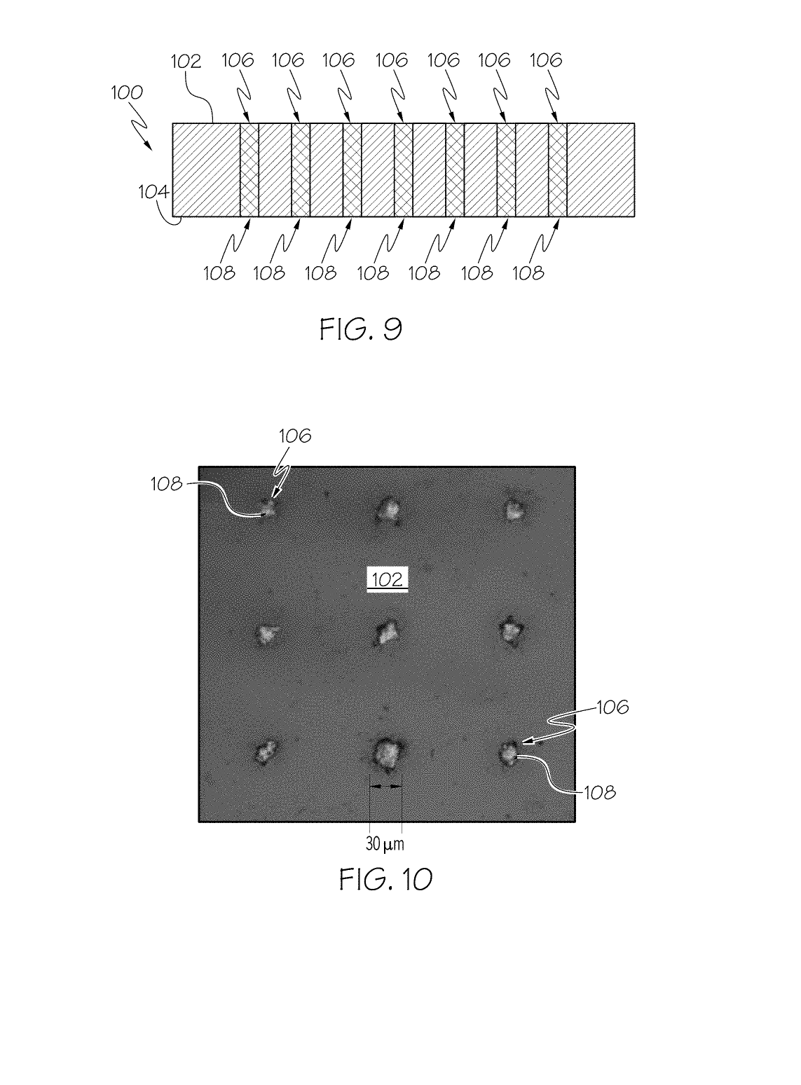

At step 240, the substrate and sacrificial metal sheet may then be separated from one another. This may be completed, for example, by prying the sacrificial metal sheet from the substrate, or vice versa. In another example, step 240 may be completed by removing the sacrificial metal sheet and/or the substrate from the apparatus described herein with respect to FIG. 1 such that the apparatus no longer provides a compressive force on the substrate and/or the sacrificial metal sheet. In some embodiments, separation may occur by applying heat or ultrasonic waves to separate the sacrificial metal sheet and the substrate. Removal of the substrate and/or the sacrificial metal sheet from the solution and the subsequent separation of the substrate and the sacrificial metal sheet will be shown and described in greater detail herein with respect to FIG. 9.

In some embodiments, metallization of vias in additional substrates may be desirable or necessary. As such, a determination may be made at step 245 as to whether to complete additional metallization of vias. If no metallization is desirable or necessary, the process may end. Otherwise, the process may move to step 250. At step 250, a determination may be made as to whether either of the solution or the sacrificial metal sheet can be reused. That is, the Galvanic displacement reaction may not result in a complete transfer of all of the metal in the sacrificial metal sheet and/or all of the metal ions in the solution in order to fill the vias of the substrate with a metal coating as described herein. As such, the sacrificial metal sheet and/or the solution may be reusable for subsequent processes as described herein. In some embodiments, the sacrificial metal sheet may be reusable for the process described herein 1 time, 2 times, 3 times, 4 times, 5 times, 6 times, 7 times, 8 times, 9 times, 10 times, or greater than 10 times. In some embodiments, the solution may be reusable for the process described herein 1 time, 2 times, 3 times, 4 times, 5 times, 6 times, 7 times, 8 times, 9 times, 10 times, or greater than 10 times.

If the sacrificial metal sheet cannot be reused (or alternatively is not desired to be reused), the process may return to step 205 to provide a new sacrificial metal sheet. If the sacrificial metal sheet can be reused, the sacrificial metal sheet may be provided at step 255 and the process may repeat at step 210 with a new substrate. If the solution is reused, the reused solution may be applied at step 225, as described in greater detail herein.

Referring now to FIG. 3, an illustrative substrate 100 and an illustrative sacrificial metal sheet 110 are schematically illustrated in a de-coupled relationship. The substrate 100 may be fabricated from any material having at least one via 106 extending through the bulk of the substrate from a first surface 102 to a second surface 104 thereof. Illustrative examples of materials that may be used for the substrate 100 include, but are not limited to, silicon and glass, and glass-ceramic. In one non-limiting example, the substrate 100 includes strengthened glass or glass-ceramic having a first compressive stress layer and a second compressive stress layer both under compressive stress, and a central tension layer under tensile stress disposed between the first compressive stress layer and the second compressive stress layer. The strengthened glass or glass-ceramic may be chemically strengthened, such as by an ion exchange strengthening process.

Although FIG. 3 illustrates a plurality of vias 106 extending through the substrate 100, embodiments are not limited thereto. In some embodiments, only one via may be provided, or multiple vias may be arranged in a manner different from what is illustrated in FIG. 3. Any number of vias in any configuration and arrangement may be provided without departing from the scope of the present disclosure.

The vias 106 may be formed from any known or yet-to-be-developed method. As a non-limiting example, the vias 106 may be formed by a laser damage and etch process wherein a pulsed laser is used to form one or more damage regions within a bulk of the substrate 100. The substrate 100 is then subjected to a chemical etchant (e.g., hydrofluoric acid, potassium hydroxide, sodium hydroxide and the like). The material removal rate is faster in the laser damaged regions, thereby causing the vias 106 to open to a desired diameter. As an example and not a limitation, methods of fabricating vias in a substrate by laser damage and etching processes are described in U.S. Pat. No. 9,517,963 and U.S. Pat. No. 9,278,886, each of which is hereby incorporated by reference.

The sacrificial metal sheet 110 provides a surface onto which metal ions are deposited during the Galvanic displacement reaction process and from which metal is deposited within the vias 106, as described herein. The sacrificial metal sheet includes a first surface 112 and a second surface 114. In the example illustrated by FIG. 3, the first surface 112 of the sacrificial metal sheet 110 (i.e., the surface that contacts the substrate 100) provides the metal that is deposited within the vias 106 of the substrate 100, as described herein.

In some embodiments, the sacrificial metal sheet 110 may be formed of any solid metal material, particularly metals that are suitable for Galvanic displacement reactions, as described in greater detail herein. In some embodiments, the sacrificial metal sheet 110 may be formed as a metal coating on a substrate, such as, for example, a metal film coated (e.g., via CVD, PVD, and/or the like) on a glass substrate, a stainless steel substrate, and/or the like. Non-limiting metal materials (including solid metal materials and metal coatings) include aluminum, iron, zinc, tin, or the like. In some embodiments, the metal selected for the sacrificial metal sheet 110 may be relative to the metal ions that are contained in the solution, so as to ensure appropriate reactivity during the Galvanic displacement reaction. As a non-limiting example, the metal material may be a metal that is less noble (i.e., more reactive and has a more negative) than the metal ions included in the solution.

Referring now to FIG. 4, the second surface 104 of the substrate 100 is illustrated as being positioned in direct contact with the first surface 112 of the sacrificial metal sheet 110. As used herein, “direct contact” means that the surfaces of substrates are in contact with one another without intervening layers disposed therebetween.

The substrate 100 and the sacrificial metal sheet 110 are maintained in a coupled relationship as shown in FIG. 4 by the application of a mechanical force onto the substrate 100, the sacrificial metal sheet 110, or both, as described in herein with respect to FIG. 1. The mechanical force provides a clamping force such that the second surface 104 of the substrate 100 remains in direct contact with the first surface 112 of the sacrificial metal sheet 110. The mechanical force should be enough to prevent the solution 120 (described below) from leaking between the substrate 100 and the sacrificial metal sheet 110, but not so great that the substrate and/or the sacrificial metal sheet 110 become damaged, such as by cracking, shattering, or the like.

Referring now to FIG. 5, an illustrative solution 120 applied to the illustrative assembly of FIG. 4 (i.e., the substrate 100 and the sacrificial metal sheet 110 in a coupled arrangement) is schematically depicted. The solution 120 contains the ions of the metal to be deposited on the first surface 112 of the sacrificial metal sheet 110 during the Galvanic displacement reaction, which results in the metal from the sacrificial metal sheet 110 being deposited within the vias 106, as described herein. Although embodiments described herein refer to the metal in the solution 120 (and to be deposited in the vias 106) as copper ions, embodiments are not limited thereto. Other illustrative metals included in the solution 120 may include, but are not limited to, silver, nickel, gold, platinum, lead, cadmium, chromium, rhodium, tin, and zinc. The solution 120 may be sulfates, cyanides, nitrates, or chlorides of any of the aforementioned metals. In one non-limiting example, the metal to be deposited is copper, and the solution is a copper salt such as copper sulfate. In another non-limiting example, the metal to be deposited is silver, and the solution is a silver salt such as silver nitrate. In yet another non-limiting example, the metal to be deposited is nickel, and the solution is a nickel salt such as nickel chloride. The solution 120 may be other particular metal salts, such as salts containing the metals listed herein, without departing from the scope of the present disclosure.

The concentration of the solution 120 is not limited by this present disclosure, and may generally be any concentration, particularly concentrations that contain a sufficient amount of metal ions that would result in a Galvanic displacement reaction, as described herein. As a non-limiting example, the solution 120 may have a concentration of ions of 0.0001M or higher.

The solution 120 may generally have any pH. As such, the pH of the solution is not limited by this disclosure. In some embodiments, an acidic pH of the solution 120 (e.g., a pH of less than 7) may facilitate the Galvanic displacement reaction.

The solution 120 is disposed about the substrate 100 such that it substantially fills all of the vias 106 that are present within the substrate 100. The substrate 100 and/or the sacrificial metal sheet 110 may be maintained within the solution 120 for the Galvanic displacement reaction to occur for a particular period of time, as described in greater detail herein.

Referring to FIG. 6, the Galvanic displacement reaction causes the more reactive (less noble) metal (e.g., aluminum) in the sacrificial metal sheet 110 at the sacrificial metal sheet 110-solution 120 interface to displace the less reactive (more noble) metal ions in the solution 120 (e.g., copper), and thereby deposit the more reactive metal within the vias 106, as described in greater detail herein.

The deposition process may be performed at room temperature, for example. As a non-limiting example, the deposition process may be performed at an ambient temperature between about 10 degrees Celsius and about 70 degrees Celsius, including about 10° C., about 20° C., about 30° C., about 40° C., about 50° C., about 60° C., about 70° C., or any value or range between any two of these values (including endpoints). In some embodiments, temperature may affect the rate of the Galvanic displacement reaction (e.g., higher temperatures may increase the reaction rate).

Compared to other processes, such as electroplating processes for example, the embodiments of the Galvanic displacement reaction process described herein provide for a metal deposition front that moves uniformly from a bottom of each of the vias 106 (e.g., the portion of each via that is adjacent to the second surface 104 of the substrate 100) to a top of each of the vias 106 (e.g., the portion of each via that is adjacent to the first surface 102 of the substrate 100). In conventional seeded electroplating, the deposition front moves from all directions as metal is deposited everywhere on the sample including outside of the via. This phenomenon leads to closing of the mouth of the via before metal is entirely filled, trapping voids within the deposit. As the metal deposition front 108 moves in only one direction in the embodiments described herein, the process requirements are simple and also provide control of the deposit quality.

FIGS. 7 and 8 schematically depict the deposited metal particles 108 advancing in a direction from the first surface 112 of the sacrificial metal sheet 110 toward the first surface 102 of the substrate 100. FIG. 8 schematically illustrates that the metal particles 108 have completely filled the vias 106. As described in greater detail herein, a via may be considered to be filled once it is partially filled, fully filled, or when an excess of metal has been deposited (i.e., overfilled). Once the vias 106 are filled with metal particles 108, the solution 120 is removed from the substrate 100 and/or the sacrificial metal sheet 110. The mechanical force applied to the substrate 100 and/or the sacrificial metal sheet 110 is removed, and the substrate 100 is separated from the sacrificial metal sheet 110 leaving the metalized vias intact, as schematically illustrated in FIG. 9.

Embodiments of the present disclosure may be enabled by the fact that the adhesive force between the sacrificial metal sheet 110 and the substrate 100 is smaller than the rest of the other forces in the system. Illustrative forces acting on the metal 108 within the vias 106, may include, but are not limited to:
F_{M-Substrate}—Adhesive force between the metal particles and the substrate;
F_{M-M}—Cohesive forces between the metal particles;
F_{M-via}— Adhesive force between the metal particles and the via wall; and
F_{Applied}— Mechanical force applied after filling the via with metal.

Thus, the condition illustrated in Equation (4) below should be satisfied for clean separation of the substrate from the substrate:

F_{M-Substrate}<F_{M-M}+F_{M-Via}+F_{Applied} (4)

The substrate 100 may optionally be dried, such as by lowering a stream of nitrogen onto the substrate 100. The substrate 100 may be cleaned and dried prior to separation from the sacrificial metal sheet 110 in some embodiments. After separation from the sacrificial metal sheet 110 and the optional cleaning and drying steps, the substrate 100 including one or more metalized vias may be then subjected to further downstream processes to incorporate it into a final product.

### Example

Coupons of glass wafers (300 μm thickness, 30 μm vias, 200 μm pitch) were provided. The through glass via pattern was limited to a 1 cm×1 cm area within a given coupon. An aluminum metal sheet (Al5051, mirror finish, 0.032″ thick, provided by McMaster Carr) was used as received. Copper sulfate (certified ACS, Fisher Scientific) was dissolved in deionized water (>18MΩ) to make the solution having a desired concentration (typically 1.0M) along with sulfuric acid at a concentration of 0.18M. Other variations of the solution included the absence of sulfuric acid as well as higher or lower concentrations of copper sulfate and sulfuric acid. The amount of sulfuric acid changes the pH of the electrolyte and potentially the reaction rate. A Teflon cell was used to carry out the deposition experiments.

The apparatus depicted in FIG. 1 was used, with an o-ring to seal the cell on top of the wafer-metal substrate sandwich to prevent leakage of the solution. The solution was introduced after the cell was assembled. The Galvanic displacement reaction was allowed to proceed for 4 hours, which was a sufficient enough time to completely fill the vias with copper metal. It is noted that, as the deposition front moves upward, the solution is pushed out of the vias. FIG. 10 is an image of the glass substrate having copper 108 deposited within the vias 106.

As there are no solid reaction by-products in this process, the solution remains fairly clean and free of any contamination enabling it to be reused multiple times, if desired.

It should now be understood that embodiments described herein are directed to methods for filling vias of a substrate with a metal using a seedless electroplating process. The methods described herein enable vias to be metalized at room temperature, do not utilize a seed layer to be deposited, and do not require the bonding of the substrate to a seed layer.

It will be apparent to those skilled in the art that various modifications and variations can be made to the embodiments described herein without departing from the spirit and scope of the claimed subject matter. Thus it is intended that the specifications cover the modifications and variations of the various embodiments described herein provided such modification and variations come within the scope of the appended claims and their equivalents.

What is claimed is:

1. A method of metalizing at least one via, the method comprising:
contacting a substrate with a sacrificial metal sheet, wherein:
the substrate comprises a first surface, a second surface, and the at least one via extending between the first surface and the second surface, and
the first surface or the second surface of the substrate contacts a surface of the sacrificial metal sheet; and
applying a solution comprising metal ions to the substrate and the sacrificial metal sheet such that a Galvanic displacement reaction occurs between the sacrificial metal sheet and the metal ions in the solution until the metal ions form a metal coating on at least a portion of one surface of the at least one via.

2. The method of claim 1, wherein the metal coating fills the at least one via.

3. The method of claim 1, wherein the metal coating partially fills the at least one via.

4. The method of claim 1, further comprising:
removing the substrate from the sacrificial metal sheet after causing the Galvanic displacement reaction.

5. The method of claim 1, wherein contacting the substrate with the sacrificial metal sheet comprises applying a mechanical force to at least one of the substrate and the sacrificial metal sheet.

6. The method claim 1, further comprising applying a mechanical force to at least one of the substrate and the sacrificial metal sheet to maintain a direct contact between the substrate and the sacrificial metal sheet.

7. The method claim 1, wherein applying the solution to the substrate and the sacrificial metal sheet comprises placing the substrate and the sacrificial metal sheet in a bath comprising the solution.

8. The method of claim 7, wherein causing the Galvanic displacement reaction comprises maintaining the substrate and the sacrificial metal sheet in the bath for a time period of about 1 minute to about 10 days.

9. The method of claim 8, further comprising maintaining the bath at a temperature of about 10° C. to about 70° C.

10. The method of claim 1, wherein:
the solution comprises copper ions; and
the sacrificial metal sheet comprises aluminum.

11. The method of claim 1, wherein the sacrificial metal sheet is a solid metal sheet or a substrate comprising a metal coating.

12. The method of claim 1, wherein the sacrificial metal sheet is a substrate comprising a metal coating.

13. The method of claim 1, wherein the metal coating is selected from the group consisting of copper, gold, silver, platinum, rhodium, lead, tin, nickel, cadmium, iron, chromium, and zinc.

14. The method of claim 1, wherein the metal coating is copper.

15. The method of claim 1, wherein the substrate comprises glass.

16. The method of claim 15, wherein the glass is a chemically strengthened glass.

17. The method of claim 1, wherein the substrate comprises silicon.

18. A method of metalizing at least one via, the method comprising:
contacting a substrate with an aluminum sheet, wherein:
the substrate comprises a first surface, a second surface, and the at least one via extending between the first surface and the second surface, and
the first surface or the second surface of the substrate contacts a surface of the aluminum sheet; and
applying a solution containing copper ions to the substrate and the aluminum sheet, resulting in a Galvanic displacement reaction between the aluminum sheet and copper ions in the solution containing copper ions until the copper ions form a copper coating on at least a portion of one surface of the at least one via.

19. The method of claim 18, further comprising:
removing the substrate from the aluminum sheet after applying the solution containing copper ions.
